(19) United States
(12) Patent Application Publication
(10) Pub. No.: US 2023/0238345 A1
(43) Pub. Date: Jul. 27, 2023

(54) HIGH-YIELDING AND ULTRAFINE PITCH PACKAGES FOR LARGE-SCALE IC OR ADVANCED IC

(71) Applicant: nD-HI Technologies Lab, Inc., Taipei City (TW)

(72) Inventor: Ho-Ming TONG, Taipei City (TW)

(21) Appl. No.: 17/707,703

(22) Filed: Mar. 29, 2022

Related U.S. Application Data
(60) Provisional application No. 63/303,544, filed on Jan. 27, 2022.

(51) Int. Cl. H01L 23/00; H01L 23/498

(52) U.S. Cl. CPC H01L 24/16; H01L 24/13; H01L 24/05; H01L 24/14; H01L 23/49833; H01L 2224/16238; H01L 2224/13147; H01L 2224/0401; H01L 2224/05666; H01L 2224/05647; H01L 2224/13655; H01L 2924/014; H01L 2224/14517; H01L 25/0655

(57) ABSTRACT

This invention provides a high-yielding and high-density/ultra-fine pitch package for ultra-large-scale ICs and advanced ICs. The package includes a substrate and a semiconductor chip. The substrate has a passivation layer covering a first surface of the substrate, wherein a plurality of holes are formed in the passivation layer, and a plurality of solder balls respectively accommodated in the plurality of holes. The semiconductor chip has a first plurality of pads, wherein a plurality of copper pillar micro-bumps respectively extend from the first plurality of pads, and the plurality of copper pillar micro-bumps are respectively connected to the plurality of solder balls.

This application claims the benefit of U.S. provisional application Ser. No. 63/303,544, filed on Jan. 27, 2022, the disclosures of which are incorporated by reference herein in its entirety.

### BACKGROUND

### Technical Field

The disclosure relates in general to integrated circuit (IC) package, and more particularly to high-yielding and high density/ultrafine pitch IC packages.

### Description of the Related Art

Deep learning for AI (Artificial intelligence), which is profoundly computationally intensive, has emerged as the most important computational workload of our generation, and the computing required to train the largest models in AI application will be increased by hundreds of thousand times. To meet the growing computational requirements of AI, a neural network chip has been designed and manufactured by Cerebras, and the size of that neural network chip 11 is about the size of entire wafer, as shown in FIG. 1. Such wafer-scale neural network chip may contain 2.6 trillion transistors and 850,000 cores on a 46,225 mm² silicon footprint. Manufacturing and operating the aforesaid wafer-scale neural network chip 11, however, are a challenge. Especially, achieving high wafer-scale chip yield and high yield to interconnect the wafer-scale neural network chip 11 to the connector 12 (FIG. 1) present a challenge with this approach.

Another extreme example of massively parallel AI application is a chiplets based SiP (system-in-a-package) as shown in FIG. 2 which was championed by researchers from University of California, Los Angeles and University of Illinois, Urbana-Champaign (the UC-UI approach). This chiplets-in-SiP contains 1024 tiles with each tile 21 comprising one logic chiplet and one memory chiplet (which equate to a total of 2,048 chiplets). These chiplets were packaged based on a wafer-scale silicon interconnect substrate 22 (15,000 mm², or equivalently 4.8″×4.8″). The chips or chiplets in the above two approaches were interconnected by wafer-level redistribution, and/or a combination of flip chip (through copper pillar micro-bumps) and wafer-level redistribution processes. In the UC-UI approach, the silicon interconnect substrate 22 was fabricated via step-and-repeat patterning with the entire wafer, and power was delivered from the edge of the silicon interconnect substrate 22. Thus, due to the large scale of the silicon interconnect substrate 22, the voltage of the input power may be gradually dropped from the edge of the center of silicon interconnect substrate 22, as shown in the bottom of the FIG. 2. A number of I/Os from each of the tiles is needed to be fanned out to the edge of the silicon interconnect substrate 22 and connected to the external connectors. The wafer-scale silicon interconnect substrate 22 was a passive substrate with the interconnect wiring between the chiplets and with “copper pillars” to connect to the chiplet I/Os.

In the 2.5D IC and 3D IC packages (FIGS. 3 and 4) for high performance computing, data centers, through silicon via (TSV) allows the interconnection between the front side of the silicon interposer or active silicon chip to its backside. TSV propels the recent surge in heterogeneous integration to form 2.5D IC and 3D IC packages, which represent the most complex packages today for high performance computing (HPC) and data centers. In the TSV enabled generic 2.5D IC structure shown in FIG. 3, the silicon interposer 31 serves as the bridge between the laminate substrate 32 and the chips 33. The chips 33 may comprises a logic die 331, a compute processor die 332 such as a FPGA, a base die 333 and a HBM (high-bandwidth memory) 334. The chips are interconnected to one another, or to the interposer through TSVs, redistribution layers (RDL) and/or copper pillar micro-bumps. 2.5D applications now include ultra-high-performance graphic processing units (GPUs), deep-learning accelerators and central processing units (CPUs) in data center networking switches and servers. Moreover, the wide-I/O memory stack 41 mounted on a logic die 42 (e.g., an application processor for cell phones) in the TSV enabled 3D IC shown in FIG. 4 is similar to the HBM in construction (FIG. 3) for 2.5D IC. In this 3D IC, a high-end logic die 43 (for HPC applications such as ASIC, GPU, CPU, or SoC die) could be attached to the laminate substrate 44.

A 2.5D IC contains the “passive” (meaning no active IC-like functions) or “active” silicon interposer with TSVs, and TSV containing “active” base dies and active HBM DRAM dies which are created by a process similar to the silicon interposer process. In contrast, a 3D IC contains only TSV containing active dies such as the wide-I/O memory and the logic or processor die. In addition to TSV, copper pillar/micro-bump is another key technology that enables 2.5D IC, 3D IC.

Achieving a high yield of the large silicon interconnect (22, FIG. 2) is a major undertaking. It poses even more of a challenge to achieve high yields if the large silicon interconnect substrate contains copper pillar micro-bumps for bonding to 2,048 chiplets in the UC-UI approach. This is because any defective bump could jeopardize silicon interconnect yield. In addition to the challenges to achieve high silicon interconnect yields, flip chip assembly poses a huge yield risk as it involves the unprecedented 2,048 chiplets in the UC-UI approach (almost 100× the number of dies in 2.5D IC). It takes a handful of dies mis-assembled to render the wafer-scale SiP defective or useless. When it comes to copper pillar micro-bump based flip chip assembly, today's mainstream production is at 40 μm pitch. Scaling beyond 40 μm pitch will enable more advanced IC nodes to be chosen for package level cost reduction in I/O pad limited applications, and far denser IC packaging for practically all single-die and multi-die high-end packaging that uses flip chip for chip to chip, chip to interposer or chip to substrate interconnection. Thus, there is a need to provide high-yielding and high-density (beyond 40 μm pitch to 10 um or lower) packages for ultra-large-scale ICs and advanced ICs which typically involve large dies and high numbers of I/Os.

### SUMMARY

Four semiconductor industry disruptions covering IC, package and system levels are taking place simultaneously: (a) from ever-bigger processor SoC die to disaggregated small die based chiplets-in-SiP (based on enabling advanced SiPs), (b) from traditional computing to near-memory computing (through 2.5D IC for instance) to in-memory computing (via 3D IC or 3D monolithic IC) to reduce the memory or bandwidth wall between processor and memory at the system level in order to more fully exploit the processor performance potentials; (c) from copper interconnect to optical interconnect, and (d) from advanced organic laminate substrate to silicon interposer and hybrid substrates with embedded active devices. The invention disclosed herein will enable the four above-mentioned industry disruptions to accelerate through migration of enabling advanced SiPs towards ultrafine micro-bump pitches.

This invention relates generally to high-yielding and high-density/ultra-fine pitch packages for ultra-large-scale ICs and advanced ICs. New processes and structures are disclosed to enable not only wafer-scale SiP but also practically all other high-end IC packaging (including 2.5D and 3D ICs) to scale from a bump pitch of 40 μm to 10 μm and beyond (e.g., 5 μm or less). Furthermore, processes, hardware and design remedies to achieve high yields will be disclosed to realize the largest ever, high-yielding wafer-scale SiP for AI and to enable continuing advancement and scaling of this wafer-scale SiP and extreme advanced SiPs, all of which depend on copper pillar micro-bumps, from 40 μm copper pillar micro-bump pitch in mainstream flip chip production today to sub-10 μm (e.g., 5 μm or less) pitches.

Traditionally it takes one defective die assembly to render the wafer-scale SiP defective or useless. Rework and redundancies are also disclosed herein to mitigate yield risks associated with the silicon interconnect fabrication and chiplets assembly. Moreover, as previously mentioned, because power is supplied from wafer edge in the UC-UI approach, there existed a voltage droop from the edge of the wafer to the center of the wafer (see FIG. 2). This can be solved by backside power supply as disclosed below.

The disclosure made herein can also be applied to other multi-die flip chip enabled packages comprising 2D flip chip, 2.5D IC, 3D IC, and other types of IC packages (such as, 3D fan-out, embedded SiPs, silicon photonics, as well as chiplets-in-SiP), particularly as the copper pillar micro-bump pitch scales beyond 40 μm pitch.

One embodiment of the present disclosure is to provide an IC packaging structure, which comprises a substrate with a passivation layer covering a first surface of the substrate, a semiconductor chip with a first plurality of pads, and a semiconductor chip with a first plurality of pads. A plurality of holes are formed in the passivation layer; and a plurality of copper pillar micro-bumps respectively extend from the first plurality of pads. The plurality of copper pillar micro-bumps are respectively connected to the plurality of solder balls.

In one aspect of the present disclosure, the copper pillar micro-bump comprises a seed layer comprising Ti/Cu or TiW/Cu; and a metal pillar extended from the seed layer, wherein the metal pillar comprises a Cu pillar covered by a Ni layer and a Ag—Sn solder layer.

In one aspect of the present disclosure, a pitch distance between two copper pillar micro-bumps is not greater than 10 μm.

In another aspect of the present disclosure, a diameter of the copper pillar micro-bump is not greater than 5 μm and a height of the copper pillar micro-bump is not greater than 10 μm.

In another aspect of the present disclosure, the IC packaging structure further comprises a set of dummy corner metal bumps located over a peripheral area of the semiconductor chip to support the semiconductor chip over the substrate.

In another aspect of the present disclosure, at least one of the plurality of holes is a two-step hole which comprises a first-step hole and a second-step hole under the first-step hole, a diameter of the top periphery of the first-step hole is greater than that of the top periphery of the second-step hole.

In another aspect of the present disclosure, a slope of a sidewall of the first-step hole is the same as or different from that of a sidewall of the second-step hole.

In another aspect of the present disclosure, the IC packaging structure further comprises a conductive barrier layer being formed to cover sidewalls of the first-step hole and sidewalls of the second-step hole.

In one more aspect of the present disclosure, the diameter of the top periphery of the first-step hole is greater than that of the top periphery of the copper pillar micro-bump.

According to anther aspect of the present disclosure, the IC packaging structure further comprises a dielectric layer covering a first surface of the semiconductor chip, wherein a plurality of holes are formed in the dielectric layer and corresponding to the first plurality of pads.

According to another aspect of the present disclosure, the plurality of copper pillar micro-bumps respectively extend from the first plurality of pads and beyond a top surface of the dielectric layer.

According to another aspect of the present disclosure, the substrate is a processor IC chip, and the semiconductor chip is a DRAM chip.

According to another aspect of the present disclosure, the substrate is a silicon interposer chip with a plurality of through silicon vias therein, and the semiconductor chip is a processor IC chip or a high-bandwidth memory (HBM) chip.

Another embodiment of the present disclosure is to provide an IC packaging structure, which comprises a composite substrate with a passivation layer covering a first surface of the substrate. A plurality of holes are formed in the passivation layer. The composite substrate includes a first silicon interposer and a second silicon interposer. The first silicon interposer and the second silicon interposer are stitched together through a first molding compound located between the first silicon interposer and the second silicon interposer. The composite substrate further includes a first redistribution layer covering the first silicon interposer and the second silicon interposer.

In one aspect of the present disclosure, the IC packaging structure further comprises a semiconductor chip stacked above and electrically connected to the first silicon interposer, wherein the first silicon interposer incorporates a power through silicon via therein, and a bottom redistribution layer is located under the first silicon interposer, such that a power voltage is supplied to the semiconductor chip through the first silicon interposer based on the power through silicon via and the bottom redistribution layer.

In another aspect of the present disclosure, the IC packaging structure further comprises a semiconductor chip stacked above and electrically connected to the composite substrate, the first redistribution layer comprises extra wires which do not transmit any signal to the semiconductor chip in the event the semiconductor chip is not defected.

In another aspect of the present disclosure, the IC packaging structure further comprises a rework chiplet stacked above and electrically connected to the composite substrate through the extra wires of the first redistribution layer in the event the semiconductor chip is defected.

In another aspect of the present disclosure, the composite substrate further includes a third silicon interposer and a fourth silicon interposer. The third silicon interposer and the fourth silicon interposer are stitched together through a second molding compound located between the third silicon interposer and the fourth silicon interposer, and the composite substrate further includes a second redistribution layer covering the third silicon interposer and the fourth silicon interposer.

According to another aspect of the present disclosure, the combination of the first silicon interposer, the second silicon interposer, the first molding compound and the first redistribution layer is a first interposer combo, and the combination of the third silicon interposer, the fourth silicon interposer, the second molding compound and the second redistribution layer is a second interposer combo; wherein the first interposer combo and the second interposer combo are stitched through a third molding compound between the first interposer combo and the second interposer combo, and the composite substrate further comprises a third redistribution layer covering the first interposer combo and the second interposer combo.

According to one aspect of the present disclosure, the IC packaging structure further comprises a semiconductor chip stacked above and electrically connected to the composite substrate, the first redistribution layer, the second redistribution layer, and/or the third redistribution layer comprises extra wires which do not transmit any signal to the semiconductor chip in the event the semiconductor chip is not defected.

According to one aspect of the present disclosure, the IC packaging structure further comprises a rework chiplet stacked above and electrically connected to the composite substrate through the extra wires in the event the semiconductor chip is defected.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates one neural network chip, the size of which is about the size of an entire wafer.

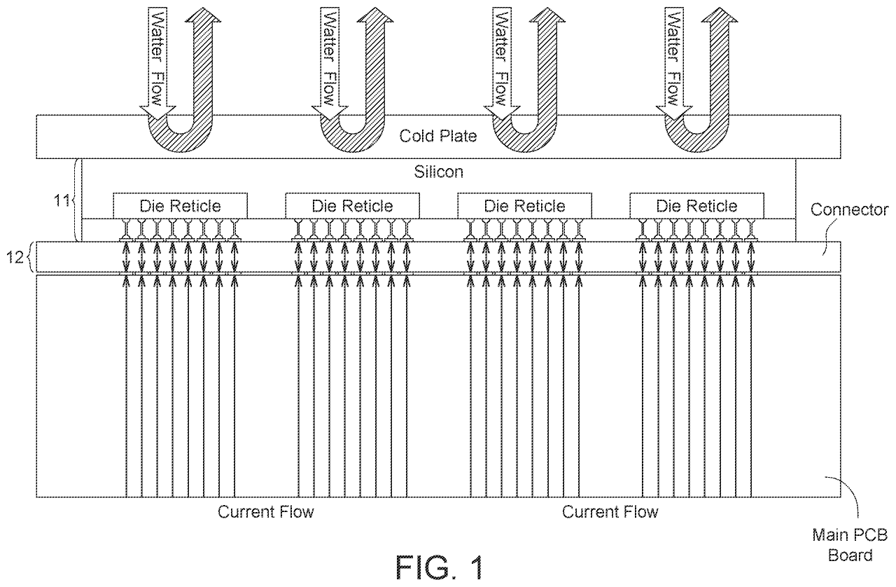

FIG. 2 illustrates an example of chiplets based SiP (system-in-a-package) with a wafer-scale silicon interconnect substrate.

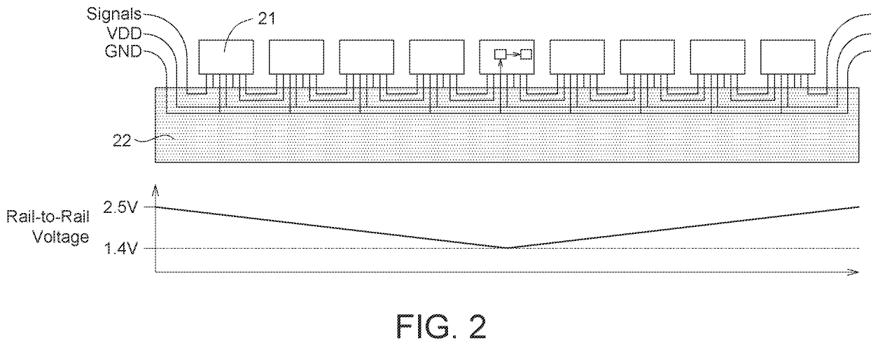

FIG. 3 illustrates an example of TSV (through silicon via) enabled generic 2.5D IC with a logic die and HBM (high-bandwidth memory) stacked over the silicon interposer.

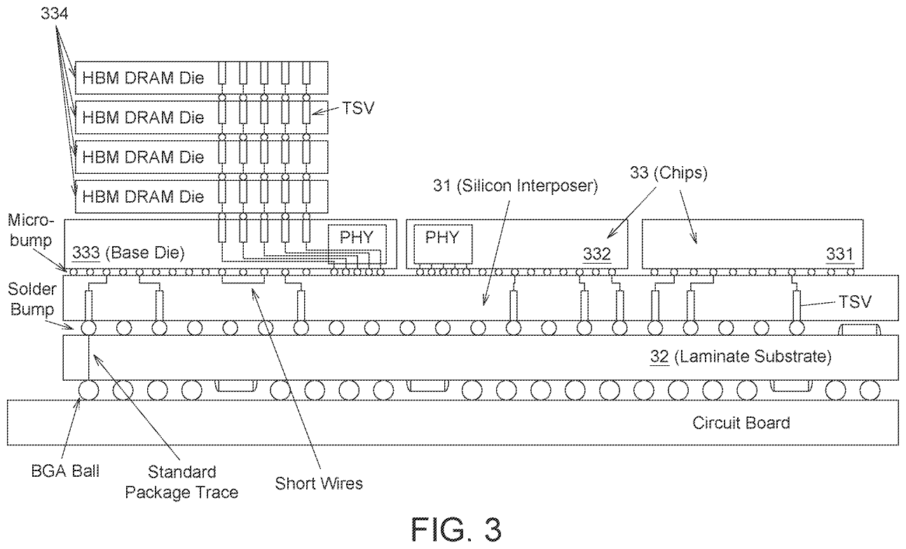

FIG. 4 illustrates an example of TSV enabled 3D IC with wide-I/O memory stack mounted on a logic die.

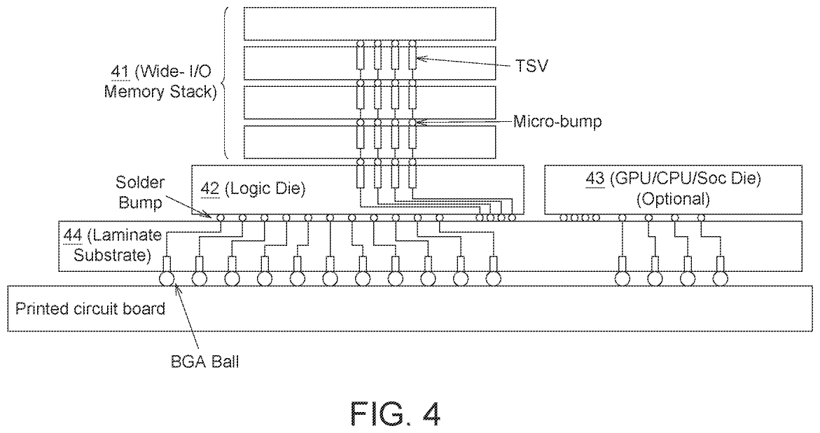

FIGS. 5(a) and 5(b) illustrates one embedment of high-yielding and ultrafine pitch IC packaging according to the present invention.

FIG. 6 illustrates the exemplary processes to rework the defective chiplet by using a localized thermal head separation.

FIG. 7 illustrates an example of stitching or interconnecting small silicon interposers to form the interposer combos and the bigger complete silicon interposer substrate.

FIG. 8 illustrates an example of high yielding/ultrafine pitch package which uses rework chiplets and extra substrate wiring to connect good chiplets while bypassing defective, not-reworked chiplets.

FIG. 9(a)-(b) illustrates another example of high yielding/ultrafine pitch package which uses rework chiplets and extra substrate wiring to connect good chiplets while bypassing defective, not-reworked chiplets.

FIG. 10(a)-(c) illustrates another embodiment of high-yielding and ultrafine pitch IC packaging according to the present invention.

FIG. 11 (a) illustrates traditional memory computing system with DRAM and processor separately attached to a PCB substrate.

FIG. 11 (b) illustrates a near-memory computing system with DRAM and processor separately attached to an interposer substrate according to the present invention.

FIG. 11 (c) illustrates an in-memory computing system with DRAM bonded to the processor according to the present invention.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The process to make the smaller copper pillar micro-bumps may include: (1) opening holes in the passivation layer (e.g., polyimide) on top of the pads of the silicon interconnect substrate to accommodate solders; (2) forming copper pillar micro-bumps on the chiplet/IC, which may comprise: (i) sputter depositing barrier/seed Ti/Cu (or TiW/Cu) layers; (ii) depositing a photoresist, (iii) opening holes in the photoresist corresponding to the pads of chiplet/IC, (iv) electroplating Cu, Ni and Ag—Sn solder on the revealed seed Ti/Cu (or TiW/Cu) layers to form the copper pillar micro-bumps, (v) lifting off the photoresist, (vi) etching off the barrier/seed layers not covered by the Cu, Ni and/or Ag—Sn; and (vii) reflowing the solder with a flux and finally cleaning the wafer. The pitch (the distance between one center of a pillar to an adjacent pillar) could be around 10 μm or less (e.g., 8-5 μm or less).

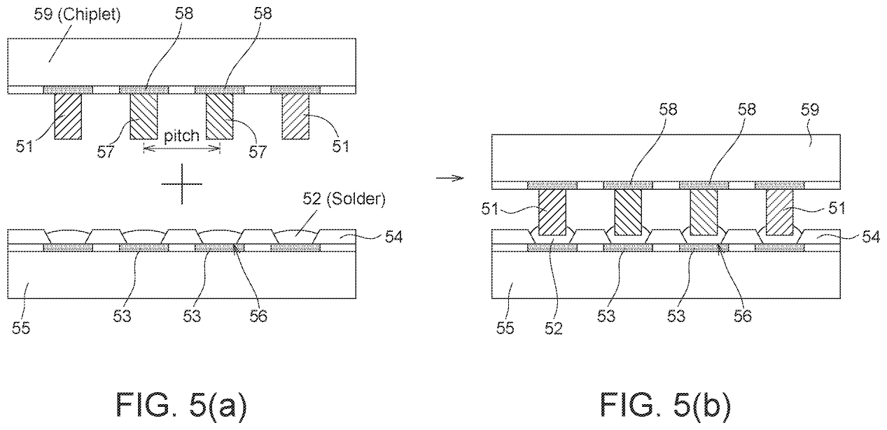

Following copper pillar micro-bump formation, the silicon interconnect substrate and the chiplet/IC with copper pillar micro-bumps could be combined or bonded together, as shown in FIG. 5. Because the copper pillar micro-bump pad pitch (˜10 μm) required by the ultra-large-scale IC or wafer-scale IC is beyond current industry mainstream capability of 40 μm, thermal compression bonding (TCB) and/or non-conductive paste (or film) are provided herein in place of the flip chip capillary underfill process. TCB tools are typically used to bond dies with tiny bumps at a bump pitch down to 40 μm in mainstream production today, both for chip-to-wafer and chip-to-substrate applications. Instead of heating the entire circuit board and all the chips on it, the thermal compression bonder picks up the die, dips it in flux just like a regular flip-chip, and places it on the substrate or PCB. There's a heater in the bond head which heats up past the melting point of solder. Then it cools down so that the solder solidifies and forms the copper pillar micro-bump joints between the IC and the substrate.

To minimize the effects of accuracy, misalignment and tilt of the TCB tool and amount of the deformation of the solder, as shown in FIG. 5(a), this invention further discloses: (a) peripheral dummy corner metal bumps 51 (e.g., copper/Ni/solder) that do not collapse or melt completely (and hold the chiplets during bonding), and (b) solder 52 deposited on pads 53 with polymeric passivation layer 54 (serving as the solder dam) on the silicon interconnect substrate 55 can be implemented to ensure sufficient solder volume (without bridging) during bonding for good electrical resistance and joint quality.

As shown in FIG. 5(a), a plurality of cavities or holes 56 are formed in the polymeric passivation layer 54 to reveal the pads 53 on the silicon interconnect substrate 55. The sidewall of the cavities or holes 56 form the solder dam to accommodate solder 52. The amount of solder 52 should be small enough to avoid bridging of adjacent solder joints, and yet large enough to achieve quality bonding while leaving some solder at the joint after intermetallics formation during bonding to facilitate subsequent chiplet rework. To ensure good joint, a multiplicity of micro-bumps 57 (such as copper pillars) can be formed on a group of tiny IC pad 58 on the IC/chiplet 59 which are matched with pads 53 on the silicon interconnect substrate 55. One variant of the flow in FIG. 5 (a) has to do with adopting the conventional process on the chiplet 59 all the way to solder plating, solder reflow and wafer cleaning. In this case, there is no need to deposit the solder 52 on the silicon interconnect substrate prior to flip chip assembly.

In today's mainstream advanced packages, the most advanced copper pillar micro-bumps involve a 40 μm pitch and a height of 25 μm (which is broken down to 15 μm copper, 5 μm Ni and 5 μm Sn—Ag). In one embodiment of this invention, when the pitch between copper pillar microbumps is 10 μm, the micro-bump diameter could be 5 μm (or less) with a height of 10 μm tall. The copper pillar microbumps could be made up of copper/Ni/Sn—Ag, copper/Sn—Ag or Ni/Sn—Ag, depending on the applications that may impose different TCB joint yield and reliability requirements.

As the diameter of the copper pillar and the solder bump becomes smaller, under-cutting during seed layer (which is the basis for copper pillar) etching removal is becoming more of a challenge; so are plating uniformity and co-planarity control. Making tiny bumps is challenging. Bonding them at finer pitches is also difficult. Flux, which dissolves the oxide in a chemical reaction, is typically used during TCB to get rid of the oxide that's on the pad for bonding. At fine-pitches and ultra-fine pitches, flux cleaning can be an issue with both flip-chip and thermal compression bonding. An alternative is to implement no-clean flux or formic acid vapor which removes oxide during TCB assembly.

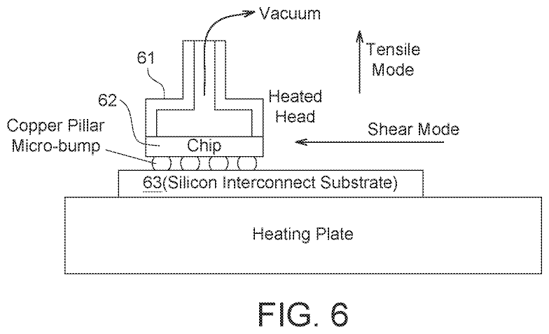

For 10 μm pitch, there could be as many as 500 million copper pillar microbumps on a 300 mm wafer. For a bump pitch beyond 10 μm, far more copper pillar microbumps will be involved. This invention discloses rework and redundancy structure and processes which can be put into good use to offset the effects caused by defective bumps under chiplets or chips following TCB assembly for wafer-level SiP and other enabling advanced SiPs. Thus, after chiplets assembly and once a bonded chiplet is deemed defective, the chiplet, the solder joints and the substrate bonding pads underneath the chiplet can be “reworked” using a localized thermal head separation method with separate substrate temperature adjustment (see FIG. 6) by sequentially: (a) removing the defective chiplet with a heated hat 61 that applies vacuum and heat to the backside of the defective chiplet 62 and removes the defective chiplet 62 after the solder softens, (b) hot redressing the bonding pads of silicon interconnection substrate 63 using a high-porosity solder wick structure suited for fine pad dimensions to remove the residual solder on the bonding pads; and (c) bonding a known-good chiplet on the redressed chip site.

In one embodiment of this invention, one option to create the wick structure is to plate Pd dendrites (coated with a solder wettable coating such as gold or Sn) on a support structure. During rework, this wick structure can be aligned to the pad to be reworked and then moved down to contact with the pads with application of local heating to the Pd dendrites to suck up the residual molten residual solder. Solder replenishing of the reworked bonding pads under the defective chip following its removal and redressing may be obviated with the use of an industrial tool such as the TCB tool for rework by optimizing the temperatures of the head and the vacuum suction plate (attached to the back of the defective chip), non-oxidizing conditions, and/or application of either a tensile and/or a shear force during chip removal. Shear strengths of lead-free micro joints tend to be significantly lower than tensile strengths, warranting its use as a low force separation below the solder's liquidus temperatures. Application of a shear force and/or a tensile force must be devoid of problems such as UBM-passivation separation which can render the pads covered by the UBM-passivation and therefore non-redressable and non-bondable following chip removal.

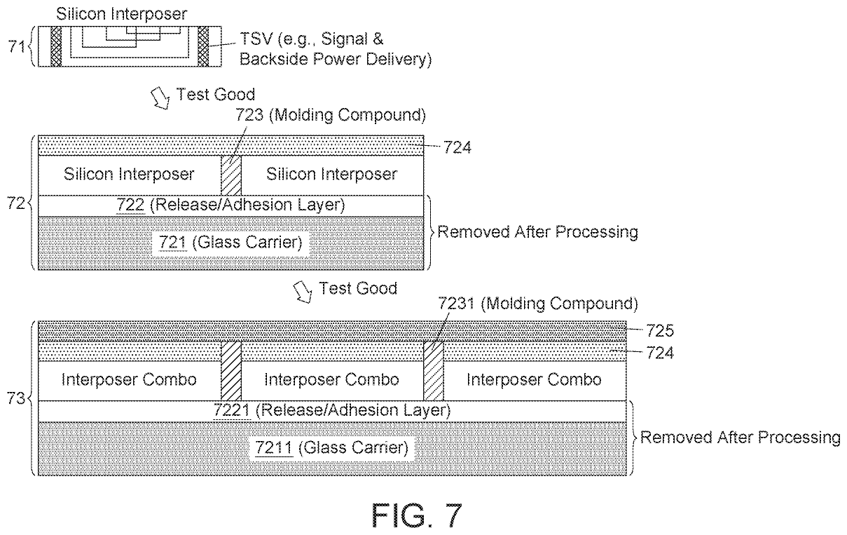

Furthermore, instead of using the wafer scale step-and-repeat processes to create the large silicon interconnect substrate which can be prone to high yield losses (particularly, as the silicon interconnect substrate is scaled up or increases in size), this invention proposes to build smaller, known-good, test-good, silicon interposers 71 (FIG. 7) which then could be progressively stitched or interconnected together by applying the chip level reconstitution and redistribution processes commonly used in fan-out processes to form interposer combos 72. As shown in FIG. 7, two or more silicon interposers 71 could be attached to a glass carrier 721 using adhesion layer 722, and then they can be stitched together and interconnected using molding compound 723 and the first redistribution layer 724 to form the interposer combos 72. Similarly, two or more interposer combos 72 could be attached to another glass carrier 7211 using adhesion layer 7221, molding compound 7231 and the second redistribution layer 725 to stitch or interconnect silicon interposer combos 72 to form the final, complete silicon interposer substrate 73 which is a composite substrate.

In another embodiment, silicon interposers 71 and interposer combos 72 can incorporate through silicon vias as back-side power supply (among other things) and redistribution layers on both the top and the bottom sides (not shown in FIG. 7), such that the silicon interposer 71, the interposer combos 72 and/or the composite silicon substrate 73 can use portion of the through silicon vias and/or bottom redistribution layers to provide power supply from the back side (as opposed to edge power supply to avoid the voltage droop issue from the edge of the silicon interconnect wafer to the center of the silicon interconnect wafer). The top side of the silicon interposer 71, the interposer combos 72 and/or the composite substrate 73 could still provide other signal-lines transmission. The final, complete silicon interposer substrate can be debonded from the release layer/adhesion layer and the glass carrier following laser debonding (and cleaning as needed) as part of the fan-out processes, and then BGA balls can be attached to the pads on the bottom side of the final silicon interconnect substrate.

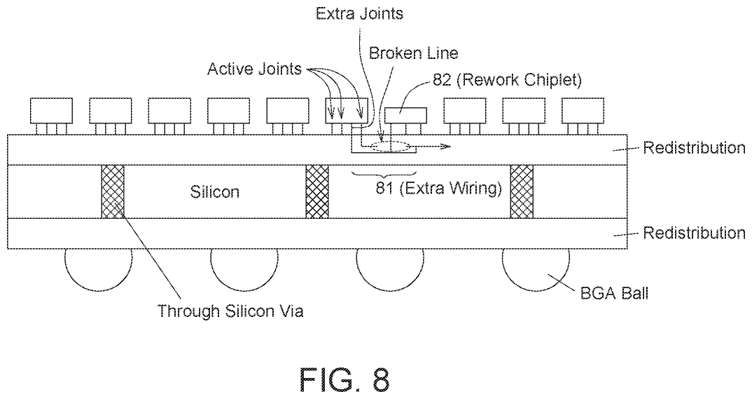

The high yielding/ultrafine pitch package according to the present invention could implement extra/redundant tiles or chiplets, extra micro-bumps and extra substrate wiring 81, as well as rework chiplets 82 (see FIG. 8) to re-route wiring (to ensure connectivity) and/or to connect to good/functioning extra chiplets in the event of defective chiplets. For systemic yield losses pertaining to defective chiplets, bad joints and interconnect wiring combined, rework chiplets 82 may be implemented through flip chip bonding using copper pillar bumps. Rework pads could also be designed in to enable rework chiplets 82 atop the silicon interconnect surface through flip chip or low-loop-height wire bonding.

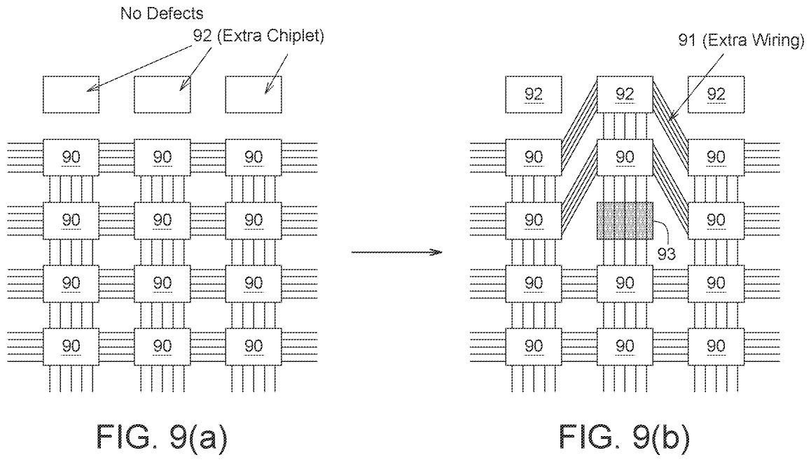

For example, as shown in FIGS. 9(a) and 9(b), the high yielding/ultrafine pitch package of the present invention could include extra chiplets 92 over the substrate (not shown) even when all chiplets 90 on the substrate are known good and there is no defected chiplets. In the event there is one defected chiplet 93 in the package, one extra chiplet 92 could be connected to the good chiplets 90 using the extra wiring 91 in the silicon interconnect redistribution layers. Of course, in another embodiment, the extra chiplets 92 could be bonded to the substrate after detecting defective chiplets.

Furthermore, in the present invention, by supplying power from the bottom as mentioned above, more space is available for designing in extra wiring 91 (see FIG. 9) in the substrate interconnect and for extra chiplets 92 to be bonded to the substrate to increase the final yield. The chips and/or chiplets can be stacked in 3D, say memory on logic, in the z-axis (thickness direction), or both in the z-direction and sideways in the x-y directions as in 2.5D IC packaging. The present invention disclosed herein can be scalable to 12″×12″ beyond what the UC-UI team is attempting to achieve (4.8″×4.8″). Also, the redistribution layers on the silicon interconnect substrate of the present invention can go finer-pitches as one migrates from implementing fan-out related line/space capabilities to implementing IC line/space capabilities (for instance, from 2 μm/2 μm to 0.5 μm/0.5 μm and beyond).

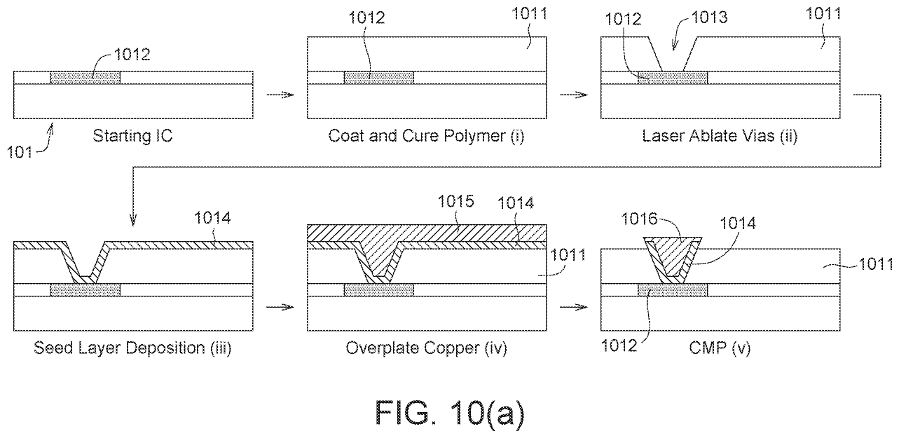

As mentioned, the pitch of the copper pillar micro-bump could be down to 10 μm or less according to the present invention. The copper pillar micro-bumps basically comprises a copper pillar with a thin Ni diffusion barrier and a Sn—Ag solder cap. Processes and structures of another embodiment of the present invention shown in FIGS. 10(a), 10(b) and 10(c) enables migration from the mainstream 40 μm pitch to beyond 10 μm pitch to a pitch of 5 μm and below. They serve as an alternative solution to the process shown in FIG. 5.

Flip chip assembly based on copper pillar microbumps has remained the workhorse when it comes to fine-pitch flip chip. 40 μm pitch is now mainstream in flip chip manufacturing based on TCB. When scaled to below 10 μm, line/space (L/S) control and copper pillar formation particularly with regard to barrier/seed layer removal, and undercut control during barrier/seed layer removal become problematic following the conventional flow of sputter deposition, photolithography, copper/pillar plating and seed layer etch. For dimensions below 10 μm, it will be advantageous to adopt excimer laser (308 nm and 248 nm short) which enables formation of embedded 2 μm/2 μm L/S and <10 μm pitch copper pillar bumps in the RDL layers. In this invention and as shown in FIGS. 10(a) and 10(b), IC/chiplet 101 can be processed separately with the substrate 102 prior to their flip chip assembly. The substrate 102 here can be the silicon interconnect substrate, another IC or an organic substrate.

As shown in FIG. 10(a) regarding IC processing: (i) a dielectric polymer layer 1011 is coated and cured on the IC/chiplet 101 with pads 1012; (ii) holes 1013 and other features (not shown) are formed in the dielectric polymer layer 1011 via excimer laser, wherein the holes 1013 are corresponding to the pads 1012; (iii) the seed/barrier layer 1014 (e.g., Ti/Cu or TiW/Cu) can be deposited by sputter deposition; (iv) copper pillar layer 1015 could be plated over the seed/barrier layer 1014; (v) thereafter, chemical mechanical polish (CMP) is used to remove overburden copper and seed/barrier layer on top of the dielectric polymer layer 1011 to form pillars 1016. Additional barrier Ni layer (not shown) could be deposited on top of the copper pillars 1016 as needed through a sequence of seed layer (e.g., Cu) deposition, photoresist deposition and hole opening, Ni plating, photoresist removal and seed layer etching. The dielectric polymer layer 1011 here can be polyimide (PI), polybenzoxazole (PBO), benzocyclobutene (BCB), epoxy/ABF (Aginomoto build-up film) or a photosensitive material. By optimizing the conditions of dielectric polymer cure and the conditions of CMP (using, for instance, three step CMP: copper first, then, seed/barrier layer and dielectric), one can create protruding copper pillars 1016 above the surface of the dielectric polymer layer 1011. This eliminates the seed layer removal problem and enables ultra-fine lines/spaces and pillars to be formed/embedded.

The substrate 102 can be processed in a similar way as the IC 101 descried in FIG. 10(a), but it has the options of creating interconnect line (not shown) and top via spaces simultaneously during the first excimer laser ablation of the dielectric polymer layer, followed by a separate excimer laser bottom via ablation in the dielectric polymer layer. As shown in FIG. 10(b), (i) a dielectric polymer layer 1021 is coated and cured on the substrate 102 with pads 1022; (ii) a first-step hole 10231 is formed in the dielectric polymer layer 1021 via the excimer laser; (iii) a second-step hole 10232 is formed in the dielectric polymer layer 1021 via the excimer laser to reveal the corresponding vias and pads 1022; (iv) the seed/barrier layer 1024 (e.g., Ti/Cu or TiW/Cu) can be deposited by sputter deposition; (v) solder layer 1025 could be plated over the seed/barrier layer 1024; (vi) thereafter, chemical mechanical polish (CMP) is used to remove the overburden solder layer 1025 and the seed layer, and the unremoved solder material layer 1025 is then reflowed to form solder balls 1026.

The two-steps holes (the combination of the first-step hole 10231 and the second-step hole 10232) created during substrate processing is intended to form a retaining wall and cavity partially filled with solder (after solder reflow during substrate processing) whose amount is enough to achieve good joints but not enough to cause solder bridging during flip chip assembly. The slope of the sidewall of the first-step hole 10231 could be the same as or different from that of the sidewall of the second-step hole 10232. The diameter of the top periphery of the first-step hole 10231 is greater than that of the top periphery of the second-step hole 10232.

Finally, the IC 101 with protruding copper pillars 1016 and the substrate 102 with solder balls 1026 in the stepped holes can be joined using TCB without needing the nonconductive paste/film, as shown in FIG. 10(c). To form covalent and van-der-Waals bonds between the dielectric layer on IC 101 and the same dielectric layer on the substrate 102, the atoms of two opposing surfaces preferably is within a few nm apart. By properly designing the copper pillar, solder and dielectric material/structures and optimizing dielectric cure and CMP conditions, it is possible to form covalent and van-der-Waals bonds between the two surfaces under the TCB temperature and pressure conditions. Using excimer laser ablation, ˜5 μm diameter and 15 μm deep holes, and ultrafine lines and spaces with a pitch down to 5 μm can be created in ABF and polyimide (PI).

Excimer laser ablation is a direct laser write technique that allows a large variety of non-photo dielectrics to be deployed including those with elastomeric characteristics, resulting in significant reduction of cost of ownership involving ultrafine lines and spaces compared to photosensitive dielectric based processes (that are prone to issues such as unstable seed layer traces and difficulties in seed layer etch). Excimer laser also allows stepped 3D via structures to be formed the dielectric layer shown in FIG. 10. Excimer laser ablation is a photo-physical process. Rather than burning, enough energy is added to disrupt molecular bonds at the surface, disintegrating the broken material bonds into the air. Ablation occurs with almost no heating or change to the underlying material or IC structure. For copper pillar micro-bumping, excimer laser ablation could also be applied with or without wet etching to removal the barrier/seed layer without damaging the copper pillar and underlying structures.

Excimer laser ablation differs from solid state laser ablation in that the former allows mask based projection covering a field area as large as 50 mm×50 mm with available wavelengths (193 nm), 248 nm and 308 nm at high throughput to create complex structures (not dependent on pattern density), whereas the latter which may damage the underlying structures and materials through its melting and evaporation patterning mode (which is pattern density dependent) uses a single spot and is limited to low-throughput, low density patterning, scribing and drilling. Following excimer laser ablation, oxygen plasma cleaning is recommended. Excimer laser ablation allows control of via side wall angle (from 65-82 degrees), selective material removal (metal pads>1 μm thick, bumps and pillars are natural stop layers) and depth and profile by number of pulses with each pulse removing a certain amount of material to reach a desired depth can be predicted and controlled.

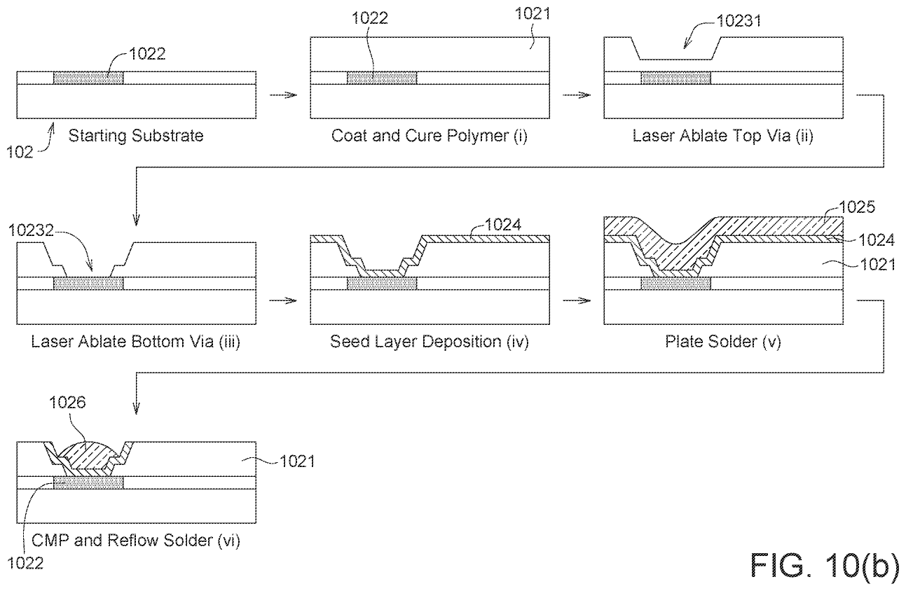

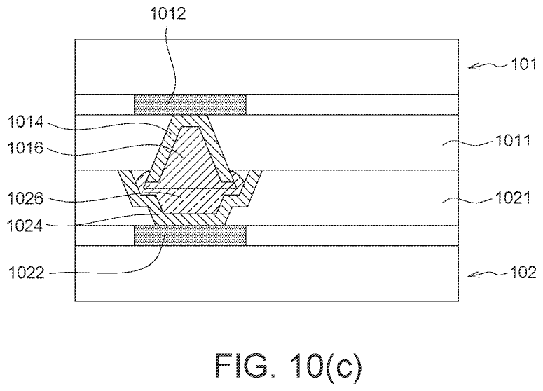

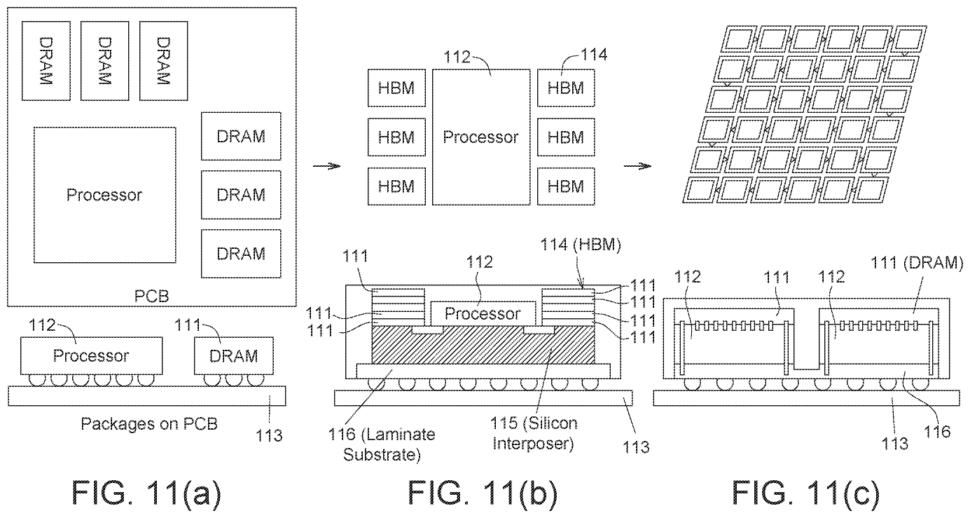

Memory systems (primarily DRAM devices) and energy efficiency present challenges for high performance computing, data centers and AI. Traditionally, DRAM 111 and processor 112 are separately attached to a PCB substrate 113, as shown in FIG. 11(a). As the rate of improvement in processor speed exceeds the rate of improvement in DRAM memory speed, this configuration creates the memory wall which has prevented processor performance to be fully exploited. Fine-pitch and ultrafine-pitch packaging according to the present invention not only will make possible the next-generation enabling advanced SiPs that accelerate the four semiconductor industry disruptions mentioned earlier, but will also enable further reduction of memory wall through near-memory or in-memory computing. As shown in FIG. 11(b) which demonstrates near-memory computing exemplified by 2.5D IC package, the HBM (high-bandwidth memory) 114 and the processor 112 is attached to the silicon interposer 115 according to the present invention. For example, the processor 112 includes a first plurality of copper pillar micro-bumps (not shown), the HBM 114 includes multiple DRAM chips 111 and the base logic die under the HBM DRAM 111 as well as the HBM DRAM dies also includes a second plurality of copper pillar micro-bumps (not shown). The silicon interposer 115 includes solder balls correspondingly bonded to a laminate substrate 116 which can contain the stepped holes and solder balls mentioned above. The silicon interposer 115 is attached to the laminate substrate 116 to form the 2.5D IC package which could be bonded to the PCB 113. Of course, he silicon interposer 115 may include through silicon vias therein.

According to FIG. 11(c) which demonstrates in-memory computing through 3D IC package, the DRAM chip 111 is directly bonded to the processor 112 according to the present invention. For example, the DRAM chip 111 can include a first plurality of copper pillar micro-bumps (not shown). The processor 112 includes solder balls correspondingly bonded to the first plurality of copper pillar micro-bumps, and those solder balls are accommodated within holes (or stepped holes) of the processor 112. The processor 112 is attached to a laminate substrate 116 to form the 3D IC package which could be bonded to the PCB 113 which can accommodate stepped holes and solder balls. According to the present invention, near-memory computing exemplified by 2.5D IC here or in-memory computing through 3D IC moves memory from the circuit board to near the logic or right on top of the logic, thereby greatly reducing data movement delays and the memory wall.

It will be apparent to those skilled in the art that various modifications and variations can be made to the disclosed embodiments. It is intended that the specifications and examples shown herein be considered as exemplary only, with a true scope of the disclosure being indicated by the following claims and their equivalents.

What is claimed is:

1. An IC packaging structure, comprising:
a substrate with a passivation layer covering a first surface of the substrate, wherein a plurality of holes are formed in the passivation layer;
a plurality of solder balls respectively accommodated in the plurality of holes; and
a semiconductor chip with a first plurality of pads, wherein a plurality of copper pillar micro-bumps respectively extend from the first plurality of pads;
wherein the plurality of copper pillar micro-bumps are respectively connected to the plurality of solder balls.

2. The IC packaging structure of claim 1, wherein the copper pillar micro-bump comprises:
a seed layer comprising Ti/Cu or TiW/Cu; and
a metal pillar extended from the seed layer, wherein the metal pillar comprises a Cu pillar covered by a Ni layer and a Ag—Sn solder layer.

3. The IC packaging structure of claim 1, wherein a pitch distance between two copper pillar micro-bumps is not greater than 10 μm.

4. The IC packaging structure of claim 3, wherein a diameter of the copper pillar micro-bump is not greater than 5 μm and a height of the copper pillar micro-bump is not greater than 10 μm.

5. The IC packaging structure of claim 1, further comprising a set of dummy corner metal bumps located over a peripheral area of the semiconductor chip to support the semiconductor chip over the substrate.

6. The IC packaging structure of claim 1, wherein at least one of the plurality of holes is a two-step hole which comprises a first-step hole and a second-step hole under the first-step hole, a diameter of the top periphery of the first-step hole is greater than that of the top periphery of the second-step hole.

7. The IC packaging structure of claim 6, wherein a slope of a sidewall of the first-step hole is the same as or different from that of a sidewall of the second-step hole.

8. The IC packaging structure of claim 6, further comprising a conductive barrier layer being formed to cover sidewalls of the first-step hole and sidewalls of the second-step hole.

9. The IC packaging structure of claim 6, wherein the diameter of the top periphery of the first-step hole is greater than that of the top periphery of the copper pillar micro-bump.

10. The IC packaging structure of claim 1, further comprising a dielectric layer covering a first surface of the semiconductor chip, wherein a plurality of holes are formed in the dielectric layer and corresponding to the first plurality of pads.

11. The IC packaging structure of claim 10, wherein the plurality of copper pillar micro-bumps respectively extend from the first plurality of pads and beyond a top surface of the dielectric layer.

12. The IC packaging structure of claim 1, wherein the substrate is a processor IC chip, and the semiconductor chip is a DRAM chip.

13. The IC packaging structure of claim 1, wherein the substrate is a silicon interposer chip with a plurality of through silicon vias therein, and the semiconductor chip is a processor IC chip or a high-bandwidth memory (HBM) chip.

14. An IC packaging structure, comprising:
a composite substrate with a passivation layer covering a first surface of the substrate, wherein a plurality of holes are formed in the passivation layer; and
wherein the composite substrate includes a first silicon interposer and a second silicon interposer, the first silicon interposer and the second silicon interposer are stitched together through a first molding compound located between the first silicon interposer and the second silicon interposer, and the composite substrate further includes a first redistribution layer covering the first silicon interposer and the second silicon interposer.

15. The IC packaging structure of claim 14, further comprising a semiconductor chip stacked above and electrically connected to the first silicon interposer, wherein the first silicon interposer incorporates a power through silicon via therein, and a bottom redistribution layer is located under the first silicon interposer, such that a power voltage is supplied to the semiconductor chip through the first silicon interposer based on the power through silicon via and the bottom redistribution layer.

16. The IC packaging structure of claim 14, further comprising a semiconductor chip stacked above and electrically connected to the composite substrate, the first redistribution layer comprises extra wires which do not transmit any signal to the semiconductor chip in the event the semiconductor chip is not defected.

17. The IC packaging structure of claim 16, further comprises a rework chiplet stacked above and electrically connected to the composite substrate through the extra wires of the first redistribution layer in the event the semiconductor chip is defected.

18. The IC packaging structure of claim 14, wherein the composite substrate further includes a third silicon interposer and a fourth silicon interposer, the third silicon interposer and the fourth silicon interposer are stitched together through a second molding compound located between the third silicon interposer and the fourth silicon interposer, and the composite substrate further includes a second redistribution layer covering the third silicon interposer and the fourth silicon interposer.

19. The IC packaging structure of claim 17, wherein the combination of the first silicon interposer, the second silicon interposer, the first molding compound and the first redistribution layer is a first interposer combo, and the combination of the third silicon interposer, the fourth silicon interposer, the second molding compound and the second redistribution layer is a second interposer combo; wherein the first interposer combo and the second interposer combo are stitched through a third molding compound between the first interposer combo and the second interposer combo, and the composite substrate further comprises a third redistribution layer covering the first interposer combo and the second interposer combo.

20. The IC packaging structure of claim 19, further comprising a semiconductor chip stacked above and electrically connected to the composite substrate, the first redistribution layer, the second redistribution layer, and/or the third redistribution layer comprises extra wires which do not transmit any signal to the semiconductor chip in the event the semiconductor chip is not defected.

21. The IC packaging structure of claim 20, further comprises a rework chiplet stacked above and electrically connected to the composite substrate through the extra wires in the event the semiconductor chip is defected.
